(19) United States
(12) Patent Application Publication
(10) Pub. No.: US 2003/0222268 A1
(43) Pub. Date: Dec. 4, 2003

(54) Light sources having a continuous broad emission wavelength and phosphor compositions useful therefor

(76) Inventors: Perry Niel Yocom, Washington Crossing, PA (US); Yongchi Tian, Princeton, NJ (US)

Correspondence Address: Birgit E. Morris, Esq., 16 Indian Head Road, Morristown, NJ, 07960, US

(21) Appl. No.: 10/372,004

(22) Filed: Feb. 21, 2003

Related U.S. Application Data
(60) Provisional application No. 60/384,609, filed on May 31, 2002.

(51) Int. Cl. H01L 21/00; H01L 33/00

(52) U.S. Cl. 257/98; 257/100; 438/22; 438/29

(57) ABSTRACT

Phosphor mixtures having a continuous emission wavelength of from about 400 to about 1500 nanometers and higher can be made from inorganic phosphors. Such phosphor mixtures can be used as light sources together with light sources or electron beam generators to provide a broad range of emission wavelength. Such phosphors can also be used to determine blood sugar levels in a human by emitting the phosphor light onto a light transmissive portion of the body, such as an ear lobe, and measuring glucose levels.

This application claims the benefit of U.S. Provisional application Serial No. 60/384,609 filed May 31, 2002.

This application is directed to light sources that continuously emit in the wavelength range of from about 400 to about 1600 nm and higher, and to phosphor compositions that will provide continuous emission in a desired range.

### BACKGROUND OF THE INVENTION

Light emitting diodes, hereinafter LEDs, are well known; they generally emit light in a range of frequency so as to produce blue light, green light, or red light. LEDs coated with phosphors that can absorb particular light wavelengths and emit light of a different wavelength, called color converter materials, are also known. For example, a blue light emitting diode can be coated with a phosphor composition that emits at a different wavelength to produce red light. White light can be obtained from a suitable mixture of blue, red and green emitting diodes and phosphors.

There is a need for a light source that emits continuously over a range of from about 400 nm to about 1600 nm and higher. This range is included within the light range of an incandescent lamp, but incandescent light emits over a broader range as well, with the major portion emitting into the far infrared.

Known phosphor mixtures do not emit continuously over the range of interest either, but rather show less, or even no emission, at certain intermediate wavelengths within the total range of emission.

It would be desirable to provide phosphor compositions that can emit continuously over a wavelength range of from about 400 to about 1600 nm and higher. Such phosphor compositions can be applied to light emitting diodes or they can be excited by electrom bombardment, as by a cathode ray tube (hereinafter CRT), to emit light continuously over the above desired range.

### SUMMARY OF THE INVENTION

We have found mixtures of inorganic phosphors that emit continuously, with little change in intensity, over a broad wavelength range, within the range of about 400 to about 1600 nm and higher. These phosphor mixtures can be excited by various light sources, such as LEDs and incandescent lamps, and can also be incorporated into a cathode ray tube (CRT) for excitation by electron bombardment.

Mixtures of inorganic phosphors of zinc and cadmium activated with copper or silver, and a co-activator, and that can form solid solutions, can be made to provide a continuous light emission over a broad wavelength range having a minimum of ripple, or discontinuities. In such case, an array of light emitting diodes that can each excite particular phosphors, or an incandescent lamp, can be used as a light source to excite the phosphor mixtures over the whole emission range. A more limited range of emission can be obtained simply by limiting the phosphor mixture to a narrower range within the broad range of emission disclosed.

### BRIEF DESCRIPTION OF THE DRAWING

FIG. 1 is a graph showing the emissivity of tungsten versus wavelength using an incandescent lamp.

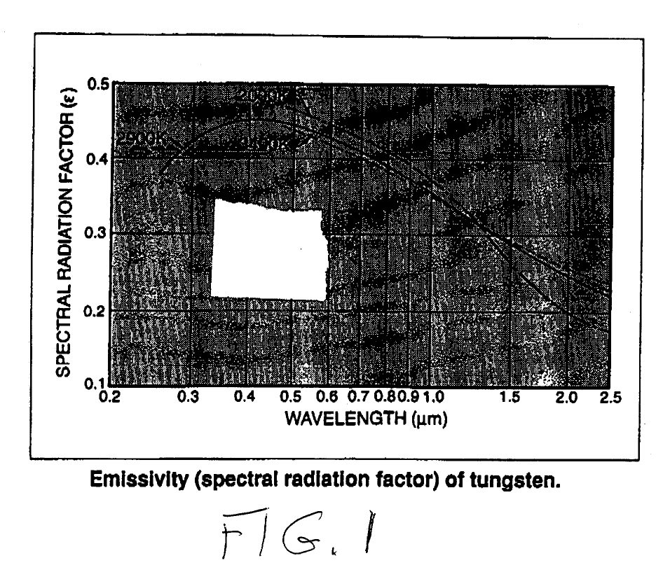

FIG. 2 is a schematic graph of emission intensity versus wavelength of a phosphor mixture of the present invention

FIG. 3 is an elevational view in cross section of a phosphor coated light emitting diode of the invention.

FIG. 4 is a schematic cross sectional view of an array of LEDs addressing a mixture of phosphors of the invention.

FIG. 5 is a schematic elevational view in cross section of an electron beam bombarded phosphor screen of the invention.

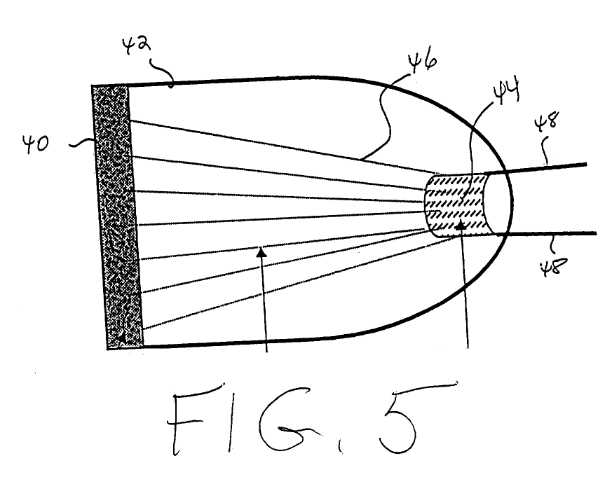

### DETAILED DESCRIPTION OF THE INVENTION

We have found mixtures of phosphors that will emit light continuously over a desired wavelength range, with very little “ripple effect” due to variations in emission intensity. These phosphor mixtures can be incorporated into various devices, including light emitting diodes, laser diodes, cathode ray tubes and other excitation sources, to produce broad and continuous wavelength emission devices.

Suitable phosphor mixtures are chosen for their individual phosphor emission wavelength to provide a desired emission range for the mixture of at least about 400 to about 1300-1600 nm or higher.

For example, phosphors that emit in the range of from about 550 to about 750 nm include calcium magnesium silicate activated with europium and/or manganese (CaMgSi₂O₆:Eu⁺², Mn⁺²) and strontium lithium silicate activated with tin and/or manganese

(Sr₂Li₂Si₂O₇:Sn⁺², Mn⁺²)

A phosphor that emits in the range of about 650 to about 750 nm is aluminum oxide activated with titanium (Al₂O₃:Ti⁺³)

A phosphor that emits in the range of about 750 to about 1100 nm is cadmium sulfide activated with copper and/or chlorine (CdS:Cu⁺²,Cl)

A phosphor that emits in the range from about 1100 to about 1300 nm is magnesium silicate activated with chromium (Mg₂SiO₄:Cr⁺⁴).

A phosphor that emits in the range from about 1200 to about 1400 nm is yttrium silicate activated with chromium (Y₂SiO₅:Cr⁺⁴)

A mixture of the above phosphors in appropriate amounts will emit in the desired range of from 550 to 1300 or even 1400 nm, without any major or sharp discontinuities. Various amounts of each phosphor will be chosen depending on the desired emission of the mixture for a particular application.

A family of II-VI phosphors based on zinc and cadmium, including their sulfides, selenides and tellurides that provide a group of solid solutions from ZnS and CdTe are particularly preferred. When activated with copper or silver and coactivated with a halide or a trivalent ion such as aluminum, gallium or lutetium, these phosphors provide luminescent emission which changes gradually as the composition of the solid solution changes. For example, ZnₓCd₁₋ₓS:Ag, Al emits at 435 nm when x=1. As more cadmium is added, longer wavelengths are obtained. If copper is substituted for silver, and the zinc content is reduced, a still longer wavelength emission is obtained. CdS activated with copper has an emission of 1000 nm. Then, by further replacing sulfur with selenium, even longer wavelengths can be obtained. When CdTe:Cu, Al is used, wavelengths up to 1500 nm or higher can be obtained.

Other broad emission range phosphors can be substituted for some of the inorganic phosphors, provided that such a substitution does not cause a serious discontinuity in the intensity of a portion of the frequency range. For example, phosphors from the alkaline earth family of calcium, strontium and barium thiogallates or thio aluminate activated with either divalent europium or trivalent cerium, can also be added. Oxide phosphors such as yttrium aluminum garnet (YAG) activated with cerium (Y₃Al₅O₁₂:Ce) and alumina activated with titanium (Al₂O₃:Ti⁺³) can be used as well. Other broad band emitters are also known to those skilled in the art.

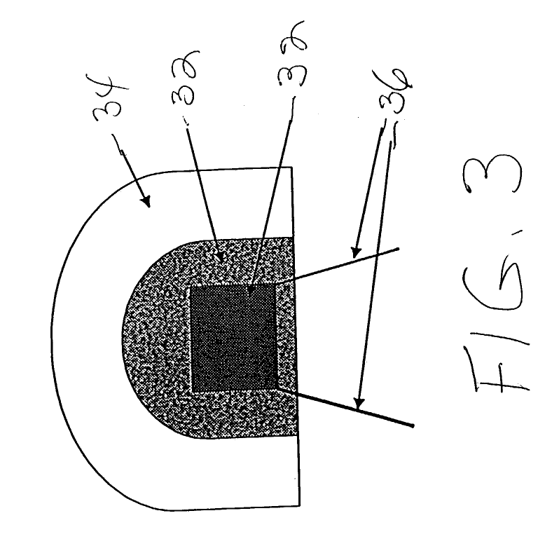

Such phosphor mixtures can be used as a thin layer which is excited by depositing the layer over a semiconductor optical diode (LED) or a laser diode. Laser diodes are employed if a high intensity output is desired. FIG. 3 is a cross sectional view of a phosphor coated light emitting diode of the invention.

Referring to FIG. 3, an LED 30 is surrounded by a phosphor layer of the invention 32. The phosphor layer has a light transparent envelope 34 thereover to encapsulate the phosphor but to allow light to pass through. Leads 36 are attached to a source of power (not shown).

Such phosphors also can be excited using an array of different LEDs to excite a layer of mixed phosphors of various compositions. For example, a phosphor layer made up of a mixture of inorganic phosphors as described above, can be deposited on a screen or a transparent substrate. An array of LEDs can be mounted on the other side of the substrate.

As the emission moves toward longer wavelengths, an incandescent lamp could also be used to excite the phosphor mixture. The change of intensity of the incandescent lamp with wavelength can be offset by the ratio of the different phosphor compositions in the mixture. Use of an incandescent lamp does have the disadvantage that it generates heat that can cause thermal quenching of the phosphor luminescence. Thus some type of coolant may need to be supplied to the phosphor layer in such case.

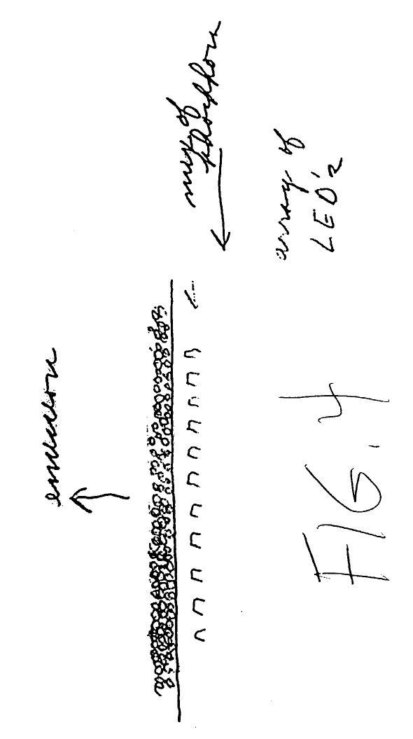

The mixture of phosphors can also be incorporated into a cathode ray tube (CRT) for excitation by electron bombardment. A CRT is shown in FIG. 4, wherein the phosphor layer 40 is applied to one end of a glass envelope 44. An electron beam generator 46 is mounted at the other end of the glass envelope 44, and leads 48 are attached to a source of power (not shown). Suitably the electron beam energy can vary from a few tens of volts up to some thousands of volts. The electron beam generator can be a thermal, cold or field emission cathode.

The phosphor mixtures of the invention can also be used if the mixture can be excited outside of a gas discharge tube for example; use of the phosphor mixture inside a gas discharge tube that contains mercury is not recommended, because the mercury will react with any sulfides present in the phosphor mixture.

The phosphor mixtures can be mixed with a liquid that forms a solid phosphor powder when dried, such as polyvinyl alcohol, or a suitable polymer or adhesive composition that encapsulates the phosphor particles and adheres the phosphor mixture to a substrate when dried, such as the glass envelope 42 of FIG. 4. Suitably, a polymer suspension can be of polycarbonate, polypropylene, polytetrafluoroethylene and the like, and cured if required. An epoxy resin is used for the final packaging of LEDs. An aluminum layer is deposited over the phosphor layer for CRTs.

The following examples illustrate phosphor mixtures useful in the invention that have emission peaks varying from about 500 to over 1400 nm. The phosphors were excited with ultraviolet (UV) light (300-420 nm) from a UV emitting LED.

### EXAMPLE 1

Part A. To ten parts of a first zinc sulfide phosphor activated with copper (ZnS:Cu⁺²) and having an emission peak of 530 nm, was added 10 parts of a first zinc-cadmium-sulfide phosphor (ZnₓCd_{y}S:Cu), wherein x is 9.5 and y is 0.5. This mixture had an emission peak of 585 nm.

Part B. A second zinc cadmium sulfide phosphor, wherein x is 8.5 and y is 1.5, (12.5 parts) was added to the phosphor mixture of Part A to give a mixture having an emission peak of 705 nm.

Part C. A second 12.5 part portion of the first zinc sulfide cadmium phosphor was added to the mixture of Part B. The emission peak now climbed to 866 nm.

Part D. Twenty parts of a magnesium silicate phosphor activated with chromium (Mg₂SiO₄:Cr⁺⁴) was then added to the mixture of Part C. This mixture had an emission peak from 902 up to 1185.

Part E. Lastly, 35 parts of a zinc silicate phosphor activated with chromium (Zn₂SiO₄:Cr⁺⁴) was added to the mixture of Part D. The resultant mixture had an emission peak of 1460 nm.

A coated LED as prepared from the above phosphor mixture emitted continuously in the range from about 500 to about 1400 nm.

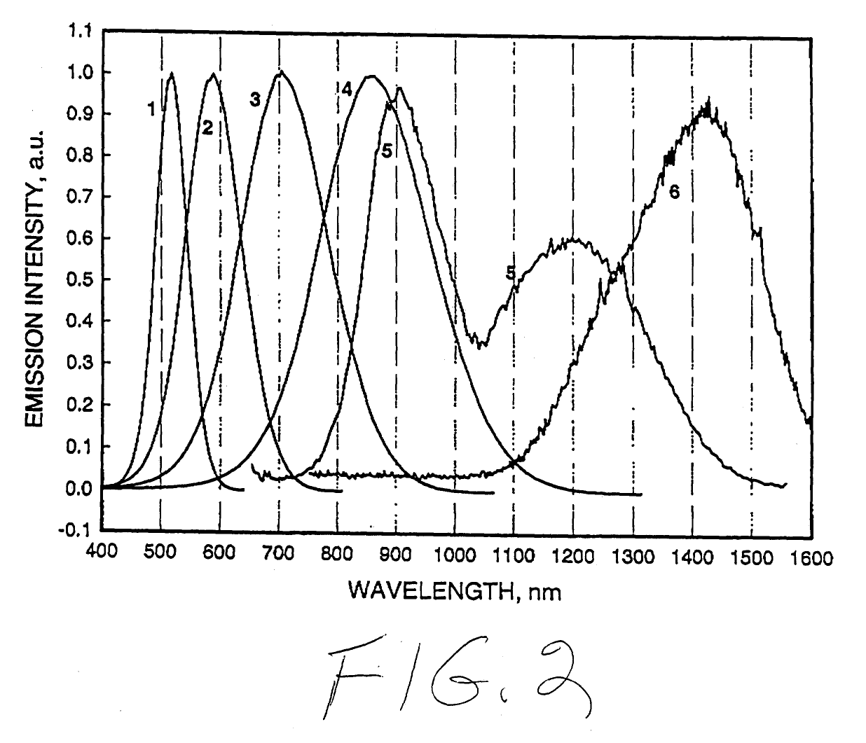

FIG. 2 is a graph of the spectra of the above phosphors, designated as 1-6. The peaks are close together and thus there is only a small ripple effect in emission intensity over the wavelength range from about 500 to about 900, with some discontinuity between about 900 and about 1400.

### EXAMPLE 2

The procedure of Example 1 was repeated except using different phosphors and mixtures. The phosphors were excited with UV light from a blue-emitting LED. The phosphor coated LED emits in the range of about 550 nm to about 1300 nm.

Part A. Ten parts of calcium magnesium silicate activated with europium and manganese (CaMgSi₂O₆:Eu⁺², Mn⁺²) had emission peaks of 458 and 710 nm.

Part B. Ten parts of YAG:Ce⁺³ were added to the phosphor of Part A. The mixture now had an emission peak of 580 nm.

Part C. Fifteen parts of silica activated with chromium (SiO₂;Cr⁺⁵) were added to the mixture of part B. The resultant emission peak was 660 nm.

Part D. Fifteen parts of alumina activated with titanium (Al₂O₃:Ti⁺³) were added to the mixture of Part C. The emission peak was now 800 nm.

Part E. Twenty parts of yttrium silicate activated with chromium (Y₂SiO₄:Cr⁺⁴) were added to the mixture of Part D. The resultant mixture had an emission peak of 1190 nm.

Part F. Lastly, 30 parts of zinc silicate activated with chromium (Zn₂SiO₄:Cr⁺⁴)were added to the mixture of Part E. The resultant mixture now had an emission peak of 1464 nm.

Other II-VI phosphors can be substituted in whole or in part for the above phosphor mixtures. These include calcium, strontium and barium thiogallates or thio aluminate activated with either divalent europium or trivalent cerium. Alkaline earth sulfides, activated with either divalent europium or trivalent cerium, can also be employed. Certain oxide phosphors, such as yttrium aluminate activated with cerium, or alumina activated with titanium or other trivalent activator, can also be substituted. Other broad band emitters are also known to those skilled in the art. By limiting the amount and emission range of the phosphors, the range of wavelength can be tailored to a particular emission range as described in the Examples.

Another utility for the present phosphor mixtures is in monitoring the concentration of various molecules in a fluid. For example, glucose concentration in the blood of a diabetic can be measured by exciting the phosphor mixture to a high intensity and transmitting the light through an ear lobe for example, to provide a wholly non-invasive glucose concentration determination method.

Diabetics must measure their blood sugar levels to adequately manage their disease. Glucose binds irreversibly to hemoglobin molecules in red blood cells. There is a direct correlation between bound glucose and blood sugar levels, as is known.

Red blood cells however have a lifetime of only about 90 days. Thus glucose levels must be measured at least every 60-90 days. However, blood sugar levels may have irregular patterns in different patients as well; one person's blood sugar can vary daily, both higher and lower than an average level of 200 mg/dl. Another person may stay at about 200 mg/dl all the time. Thus, although the average may be about the same for these two persons, they require different remedies.

Thus it would be highly desirable for a patient to be able to monitor blood glucose levels at home on a daily basis, rapidly and simply, to determine their daily blood sugar levels.

Color reflectance meters are well known and readily available for this purpose. They require a light source with filters and a lens to detect a color change within a spectral range of 500-1000 nm as evidence of the blood glucose level. The present mixtures, which operate in this range, can be used to form the light source.

There is a known approximate relationship between hemoglobin A,(HbAlc) value and a corresponding blood sugar value, as reported in the Diabetes Control and Complications Trial.

The phosphor mixture is excited to a high intensity, and the light transmitted to pass through a thin or translucent body region, such as an ear lobe for example, where glucose concentration in blood can be determined. This test method has the advantage that it is totally non-invasive, that no needles are required and, very importantly, that no blood needs to be handled, by the patient or anyone else.

Although described in terms of particular embodiments, one skilled in the art will understand that various phosphors can be substituted in whole or in part for the phosphors described above. The invention is not meant to be limited to particular embodiments, but only by the scope of the appended claims.

We claim:

1. A light source having a broad, continuous emission wavelength of from about 435 nm up to 1600 nm and higher, comprised of a mixture of inorganic phosphors activated with copper or silver and co-activated with a halide or a trivalent ion when excited by a source of light energy.

2. A light source having a broad, continuous emission wavelength of from about 435 nm up to 1600 nm and higher, comprised of a mixture of II-VI phosphors activated with copper or silver and co-activated with a halide or a trivalent ion when excited by electron bombardment.

3. a light source according to claim 2 wherein said II-VI phosphors are of zinc and cadmium.

4. A light source according to claim 1 wherein said inorganic phosphors are selected from the group consisting of solid solutions of zinc sulfide, zinc selenide, zinc telluride, cadmium sulfide, cadmium selenide, cadmium telluride, metal silicates, metal aluminum garnet and alumina.

5. A light source according to claim 2 wherein said II-VI phosphors are selected from the group consisting of solid solutions of zinc sulfide, zinc selenide, zinc telluride, cadmium sulfide, cadmium selenide, cadmium telluride, metal silicates, metal aluminum garnet and alumina.

6. A cathode ray tube comprising a glass envelope including an electron beam terminated with a screen wherein the screen is coated with a layer of the phosphor mixture of claim 1.

7. A light emitting diode coated with a phosphor layer mixture of claim 1, in turn coated with a light transparent layer.

8. A phosphor mixture comprising phosphors having an emission frequency varying from about 600 to about 1600 nm.

9. A phosphor mixture according to claim 8 wherein said phosphors comprise a mixture of strontium lithium silicate activated with divalent tin or manganese; alumina activated with trivalent titanium; cadmium sulfide activated with copper and magnesium silicate activated with chromium.

10. A phosphor mixture according to claim 8 wherein said phosphors comprise a mixture of calcium-magnesium silicate activated with divalent europium or manganese; alumina activated with titanium; cadmium sulfide activated with copper; magnesium silicate activated with chromium; and yttrium silicate activated with chromium.

11. A light emitting diode comprising a phosphor layer surrounding a light emitting diode wherein said phosphor layer is a phosphor mixture according to claim 9.

12. A light emitting diode according to claim 11 wherein said diode emits light in the ultraviolet light range of 300 to 420 nm.

13. A light emitting diode comprising a phosphor layer surrounding a light emitting diode wherein said phosphor layer is a phosphor mixture of claim 11.

14. A light source comprising a phosphor layer of claim 11 on a transparent substrate and an array of light emitting diodes of varying emission frequency mounted behind said substrate.

15. A non-invasive method for monitoring glucose concentration in a diabetic patient using as a light source the phosphor mixture of claim 1, illuminating a portion of the body that will transmit light therethrough, and measuring the light transmission.

16. A method according to claim 12 wherein the body portion is an ear lobe.

17. A method for monitoring glucose concentration in a diabetic patient using as a light source the phosphor mixture of claim 2.

18. A method for monitoring glucose concentration in a diabetic patient using as a light source the phosphor mixture of claim 7.
